(19) United States
(12) Patent Application Publication
(10) Pub. No.: US 2024/0313084 A1
(43) Pub. Date: Sep. 19, 2024

(54) HIGH ELECTRON MOBILITY TRANSISTOR AND HIGH ELECTRON MOBILITY TRANSISTOR FORMING METHOD

(71) Applicant: HiPer Semiconductor Inc., Grand Cayman (KY)

(72) Inventor: WEI-CHIH HO, Zhubei City (TW)

(21) Appl. No.: 18/185,946

(22) Filed: Mar. 17, 2023

(51) Int. Cl. H01L 29/66; H01L 29/20; H01L 29/45; H01L 29/778

(52) U.S. Cl. CPC H01L 29/66462; H01L 29/2003; H01L 29/452; H01L 29/7786

(57) ABSTRACT

A high electron mobility transistor (HEMT) and method for forming the same are disclosed. The method includes the following steps: forming a channel layer on a substrate; forming a barrier layer on the channel layer; defining a gate structure on the barrier layer; defining a source ohmic contact recess and a drain ohmic contact recess, wherein each of the source ohmic contact recess and the drain ohmic contact recess has a sidewall portion and a bottom portion; depositing an un-doped layer covering the channel layer, the barrier layer, the gate structure, the source ohmic contact recess and the drain ohmic contact recess such that the electron transporting area is rebuilt at the interface around the bottom portion and the sidewall portion of the source ohmic contact recess and the drain ohmic contact recess.

### BACKGROUND

### 1. Technical Field

The present disclosure is related a low ohmic contact fabrication method for compound semiconductor, such as a high electron mobility transistor (HEMT), by providing an extended electron transporting area around an interface of a sidewall portion and a bottom portion of a source ohmic contact recess and a drain ohmic contact recess to improve a contact resistance of a high electron mobility transistor, and a high electron mobility transistor forming method forming the same.

### 2. Description of the Related Art

High electron mobility transistors (HEMT) with a p-type doped GaN layer are the most common commercially available high electron mobility transistors applied in high power and high frequency devices. In order to continually improve the efficiency of high power and high frequency devices, a lower Ron parameter has become more and more important. Recess Source/Drain contact structures are widely applied in an Au-free process of GaN high electron mobility transistors, and research has already proven that only the sidewall of the source/drain region provides electron transport. However, in some approaches, such as U.S. Pat. No. 7,432,142 B2 and U.S. Pat. No. 9,634,107 B2, because the source/drain bottom contacts uGaN, which has high resistance of >1e6 ohm and lacks two-dimensional electron gas (2DEG) on the interface therebetween to form an electron transport path. Thus, U.S. Pat. No. 7,432,142 B2 and U.S. Pat. No. 9,634,107 B2 cannot provide a sufficient electron transport path at the bottom of the S/D contact region either to lower the Ron parameter or to improve a contact resistance of a high electron mobility transistor.

### SUMMARY

It is an object of the present invention to provide a high electron mobility transistor with an extended electron transporting area around an interface of a sidewall portion and a bottom portion of a source ohmic contact recess and a drain ohmic contact recess to improve a contact resistance of a high electron mobility transistor.

It is another object of the present invention to provide a high electron mobility transistor forming method to provide a high electron mobility transistor with an extended electron transporting area around the interface of the sidewall portion and the bottom portion of the source ohmic contact recess and the drain ohmic contact recess to improve a contact resistance of the high electron mobility transistor.

To achieve the above objectives, the present disclosure provides a high electron mobility transistor including a substrate, a channel layer, a barrier layer, a gate structure, a source ohmic contact recess, a drain ohmic contact recess, an electron transporting area, a source ohmic contact and a drain ohmic contact. The channel layer is disposed on the substrate. The barrier layer is disposed on the channel layer. The gate structure is disposed on the barrier layer, and the electron transporting area is formed at an interface between the barrier layer and the channel layer additional to the interface beneath the gate structure. The source ohmic contact recess and a drain ohmic contact recess access the barrier layer, wherein each of the source ohmic contact recess and the drain ohmic contact recess has a bottom and a sidewall portion. The un-doped layer covers the barrier layer, the gate structure, the source ohmic contact recess and the drain ohmic contact recess, and a polarization of two-dimensional electron gas (2DEG) under the bottom portion is enhanced. The source ohmic contact and the drain ohmic contact individually cover the source ohmic contact recess and the drain ohmic contact recess respectively.

To achieve the above objectives, the present disclosure further provides a high electron mobility transistor forming method including the following steps: forming a channel layer on a substrate; forming a barrier layer on the channel layer; defining a gate structure on the barrier layer such that an electron transporting area is formed at an interface between the barrier layer and the channel layer additional to the interface beneath the gate structure; defining a source ohmic contact recess and a drain ohmic contact recess, wherein each of the source ohmic contact recess and the drain ohmic contact recess has a bottom and a sidewall portion; depositing an un-doped layer covering the barrier layer, the gate structure, the source ohmic contact recess and the drain ohmic contact recess, and a polarization of two-dimensional electron gas (2DEG) under the bottom portion is enhanced; and depositing a source ohmic contact and a drain ohmic contact covering the source ohmic contact recess and the drain ohmic contact recess.

The high electron mobility transistor and a high electron mobility transistor forming method have the advantages listed below: the Ron performance of the high electron mobility transistor of the present disclosure is further lowered; the geometric shape of the sidewall portion and the bottom portion increase the electron transporting area such that the source contact resistance and drain contact resistance of the high electron mobility transistor of the present disclosure are improved. The forming method of the present disclosure also solves the process control capability issues of manufacturing high electron mobility transistors. The increased electron transporting area also enhances the polarization of two-dimensional electron gas (2DEG) such that electrons can be transported easily. Because of an embodiment wherein the barrier layer (AlGaN) is etched through to access the channel layer, requirements for controlling an ultra-low etching rate, a retained barrier thickness, or a thermal budget can be suspended.

In this invention, an un-doped layer (an un-doped nitride base) is applied to rebuild the electron transporting area around the sidewall and bottom of the source ohmic contact recess and the drain ohmic contact recess for the 2DEG; 2DEG exists at the un-doped layer and the channel layer (uGaN) interface. Applying the un-doped layer to rebuild the electron transporting area around the sidewall and bottom of the source ohmic contact recess and the drain ohmic contact recess for the 2DEG will offer more electron transport paths from the sidewall and bottom area of the source ohmic contact recess and the drain ohmic contact recess, and it will lower the contact resistance, too.

### BRIEF DESCRIPTION OF THE DRAWINGS

FIG. 1A is a flow chart showing a first embodiment of a high electron mobility transistor forming method;

FIG. 1B is a flow chart showing a second embodiment of a high electron mobility transistor forming method;

FIG. 1C is a flow chart showing a third embodiment of a high electron mobility transistor forming method;

FIG. 1D is a flow chart showing a fourth embodiment of a high electron mobility transistor forming method;

FIG. 1E is a flow chart showing a fifth embodiment of a high electron mobility transistor forming method;

FIG. 2A to FIG. 2D illustrate the first embodiment of a high electron mobility transistor forming method forming a first embodiment of a high electron mobility transistor of the present disclosure;

FIG. 3A to FIG. 3D illustrate the first embodiment of a high electron mobility transistor forming method forming a second embodiment of a high electron mobility transistor of the present disclosure;

FIG. 4A to FIG. 4D illustrate the second embodiment of a high electron mobility transistor forming method forming a third embodiment of a high electron mobility transistor of the present disclosure;

FIG. 5A to FIG. 5E illustrate the third embodiment of a high electron mobility transistor forming method forming a fourth embodiment of a high electron mobility transistor of the present disclosure;

FIG. 6A to FIG. 6E illustrate the fourth embodiment of a high electron mobility transistor forming method forming a fifth embodiment of a high electron mobility transistor of the present disclosure;

FIG. 7A to FIG. 7D illustrate the fourth embodiment of a high electron mobility transistor forming method forming a sixth embodiment of a high electron mobility transistor of the present disclosure;

FIG. 8A to FIG. 8D illustrate the fourth embodiment of a high electron mobility transistor forming method forming a seventh embodiment of a high electron mobility transistor of the present disclosure; and

FIG. 9A to FIG. 9D illustrate the fifth embodiment of a high electron mobility transistor forming method forming an eighth embodiment of a high electron mobility transistor of the present disclosure.

### DETAILED DESCRIPTION OF THE EMBODIMENTS

In order to make the structure and characteristics as well as the effectiveness of the present disclosure further understood and recognized, a detailed description of the present disclosure is provided as follows, along with embodiments and accompanying figures.

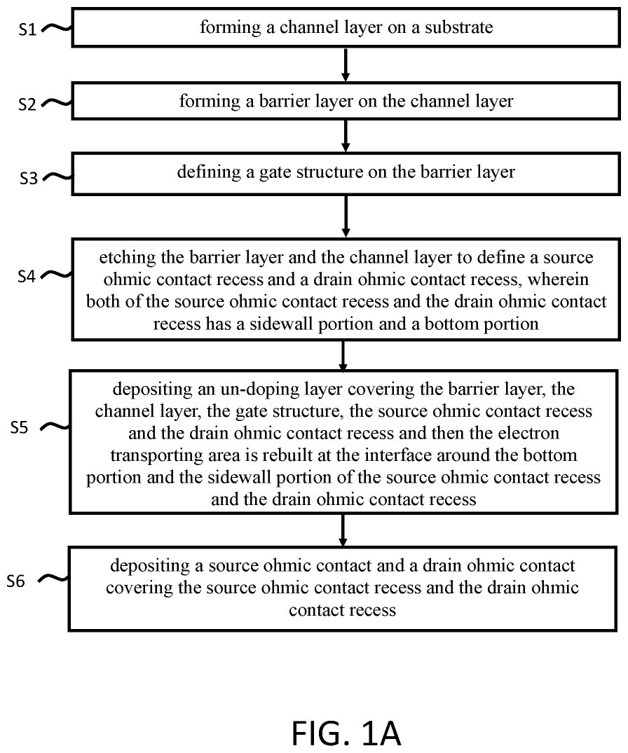

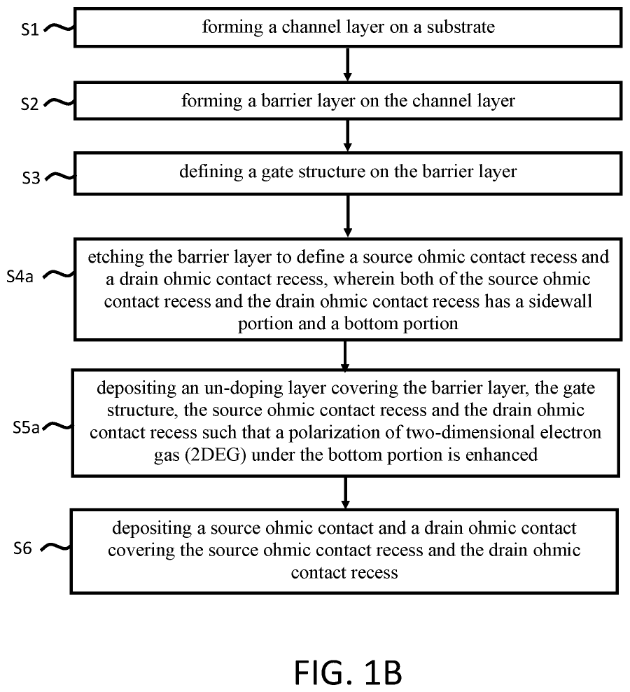

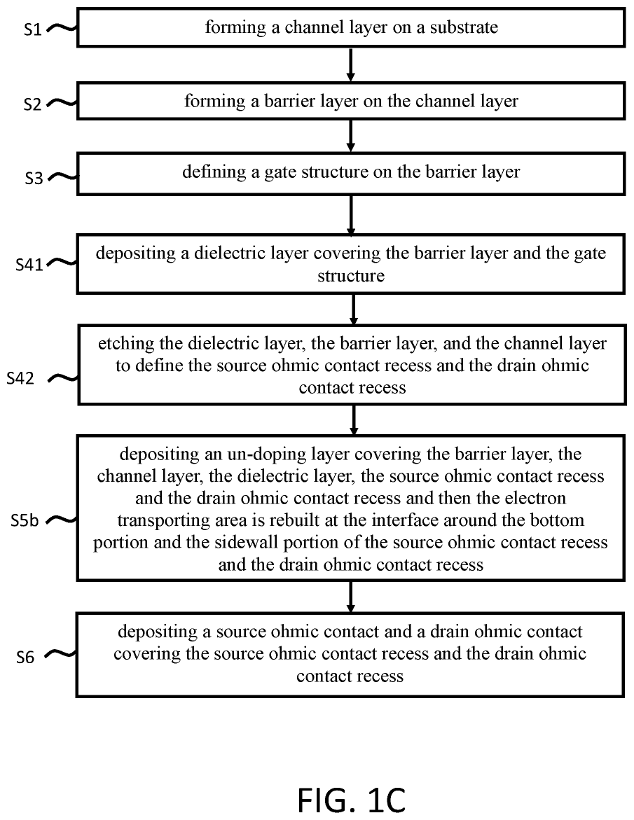

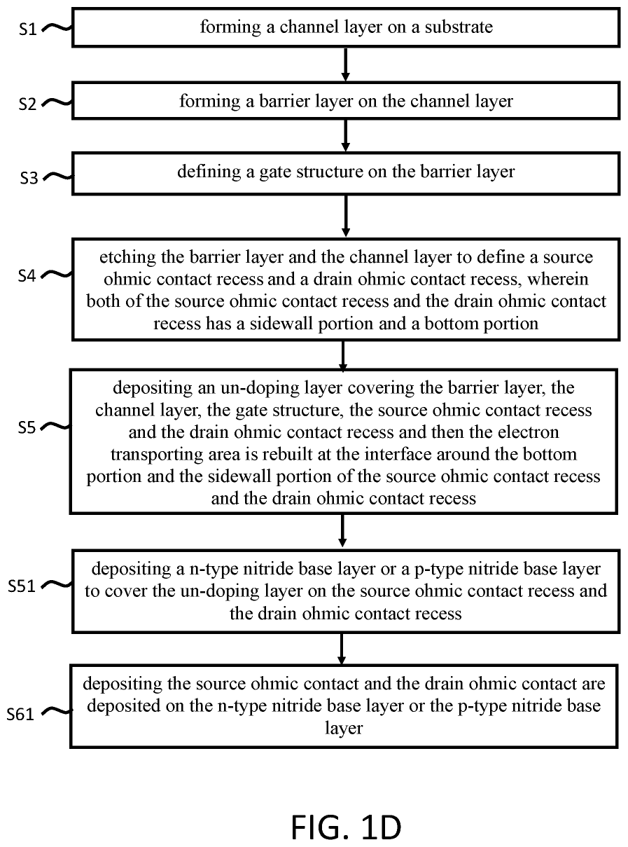

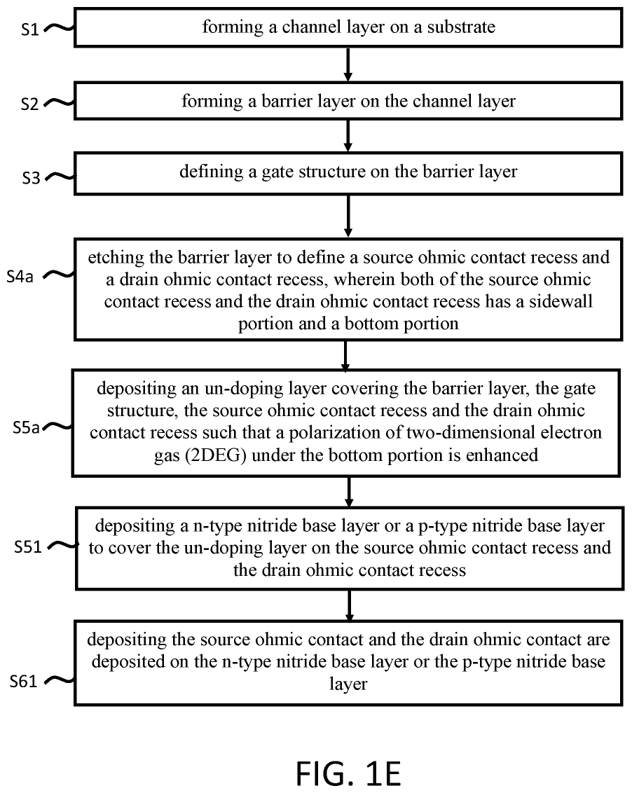

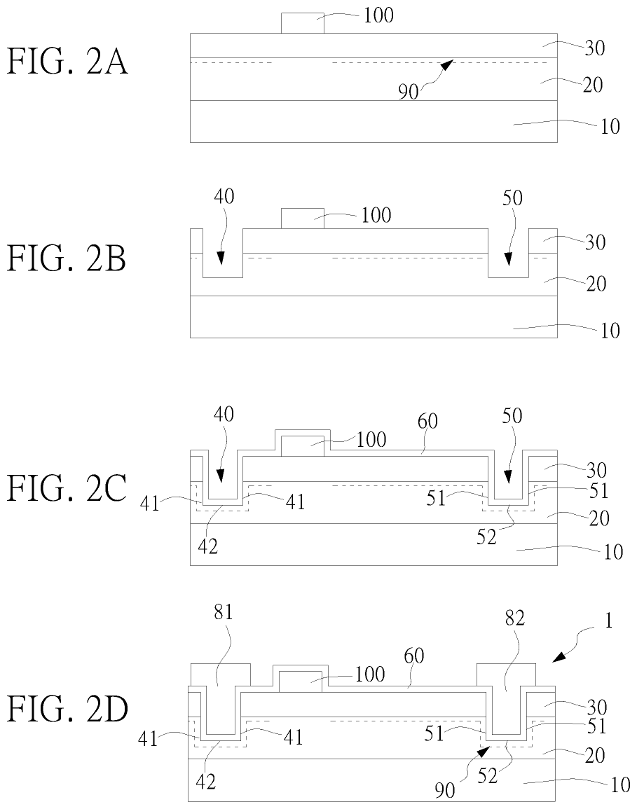

Please refer to FIG. 1A and to FIG. 2A to FIG. 2D, which present a flow chart showing a first embodiment of a high electron mobility transistor forming method and a first embodiment of a high electron mobility transistor of the present disclosure formed by the first embodiment of the method.

As shown in FIG. 1A, the first embodiment of the high electron mobility transistor forming method includes the following steps:

S1: Forming a channel layer on a substrate.

As shown in FIG. 2A, the channel layer 20 is disposed on the substrate 10. In this embodiment, the substrate 10 is a Si, SiC or sapphire substrate, and the channel layer 20 is a graded AlₓGa₁₋ₓ N or AlN/GaN supper lattice layers layer.

S2: Forming a barrier layer on the channel layer.

As shown in FIG. 2A, the barrier layer 30 is disposed on the channel layer 20. In this embodiment, the barrier layer 30 is an AlGaN layer.

S3: Defining a gate structure on the barrier layer.

As shown in FIG. 2A, the gate structure 100 is defined on the barrier layer 30. In this embodiment, the gate structure 100 is a p-type GaN structure; however, the present disclosure is not limited to this embodiment, a n-type GaN structure or metal composition layer also applicable. It is noted that an electron transporting area 90 for enhancing a two-dimensional electron gas (2DEG) is formed at the interface between the barrier layer 30 and the channel layer 20 additional to the interface beneath the gate structure 100.

S4: Etching the barrier layer and the channel layer to define a source ohmic contact recess and a drain ohmic contact recess, wherein each of the source ohmic contact recess and the drain ohmic contact recess has a sidewall portion and a bottom portion.

As shown in FIG. 2B, in this embodiment, the source ohmic contact recess 40 and the drain ohmic contact recess 50 are defined by etching through the barrier layer 30 and accessing the channel layer 20. Each of the source ohmic contact recess 40 and the drain ohmic contact recess 50 has a sidewall portion 41, 51 and a bottom portion 42, 52. In this embodiment, the sidewall portions 41, 51 and the bottom portions 42, 52 of the source ohmic contact recess 40 and the drain ohmic contact recess 50 are formed in a rectangle shape. It is noted that the depth of the source ohmic contact recess 40 and the drain ohmic contact recess 50 ranges from 0.5 nm to a half of a depth of the sum of the depth of the channel layer 20 and the depth of the barrier layer 30(epi layer).

S5: depositing an un-doping layer covering the barrier layer, the channel layer, the gate structure, the source ohmic contact recess and the drain ohmic contact recess and then the electron transporting area is rebuilt at the interface around the bottom portion and the sidewall portion of the source ohmic contact recess and the drain ohmic contact recess.

As shown in FIG. 2C, the un-doped layer 60 covers the channel layer 20, the barrier layer 30, the gate structure 100, the source ohmic contact recess 40, and the drain ohmic contact recess 50 such that the electron transporting area 90 is rebuilt at the interface around the sidewall portions 41, 51 and the bottom portions 42, 52 of the source ohmic contact recess 40 and the drain ohmic contact recess 50. In this embodiment, the sidewall portions 41, 51 and the bottom portions 42, 52 of the source ohmic contact recess 40 and the drain ohmic contact recess 50 are formed in a rectangle shape to allow the electron transporting area 90 to be rebuilt to the rectangle-shaped interface around the sidewall portions 41, 51 and the bottom portions 42, 52. The rebuilt the electron transporting area 90 around the rectangle-shaped interface around the sidewall portions 41, 51 and the bottom portions 42, 52 can enhance the two-dimensional electron gas (2DEG) and source/drain contact resistances can be reduced consequently. According to one embodiment of the present disclosure, the un-doped layer 60 can be a GaN layer, an AlN layer, an AlGaN layer, an InAlGaN layer, a high Al fraction layer or an AlN/AlGaN composition layer and formed by atomic layer deposition (ALD) or metal organic chemical vapor deposition (MOCVD). According to one embodiment of the present disclosure, the thickness of the un-doped layer 60 ranges between 0.5 nm and 30 nm.

S6: Depositing a source ohmic contact and a drain ohmic contact covering the source ohmic contact recess and the drain ohmic contact recess.

As shown in FIG. 2D, the source ohmic contact 81 and the drain ohmic contact 82 are deposited to cover the source ohmic contact recess 40 and the drain ohmic contact recess 50 respectively, and the high electron mobility transistor 1 is consequently formed. In this embodiment, both the source ohmic contact 81 and the drain ohmic contact 82 are metal stacks made of Ti, Al, TiN, or Si.

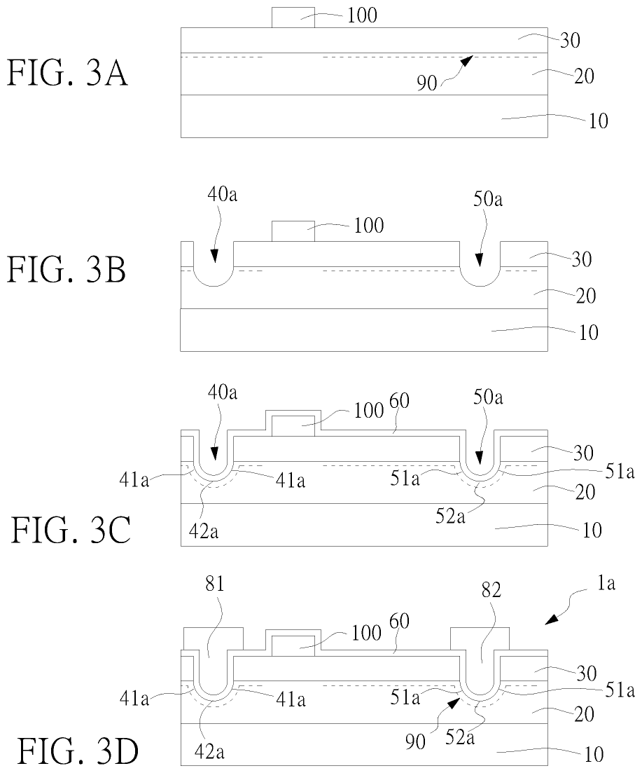

Please refer to FIG. 3A to FIG. 3D, which is a second embodiment of a high electron mobility transistor of the present disclosure formed by the first embodiment of the forming method. It is noted that, as shown in FIG. 3A to FIG. 3D, the difference between the first embodiment of a high electron mobility transistor 1 and the second embodiment of a high electron mobility transistor 1a is that the sidewall portions 41a, 51a and the bottom portions 42a, 52a are formed in an arc shape in the second embodiment. Thus, the same processing method, i.e., S1 to S3, and S5 to S6, are omitted. The S4 for etching the rounded recess shape is presented as follows: As shown in FIG. 3B, the rounded recess shape of the sidewall portions 41a, 51a and the bottom portions 42a, 52a can be formed by using a slow slope PR profile with low bias power to form the rounded recess shape of the sidewall portions 41a, 51a and the bottom portions 42a, 52a. It is noted that the depth of the source ohmic contact recess 40a and the drain ohmic contact recess 50a ranges from 0.5 nm to a half of a depth of the sum of the depth of the channel layer 20 and the depth of the barrier layer 30(epi layer). It is noted that the present disclosure is not limited to the two above-mentioned embodiments; the sidewall portion and the bottom portion can also be formed in another geometric shape, such as a trapezoidal shape or a U shape, to increase a cross section of the electron transporting area 90.

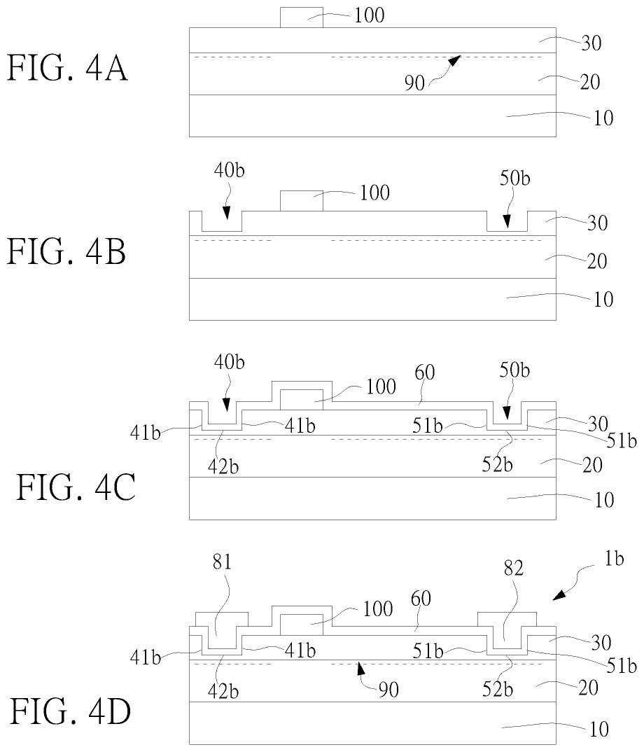

Please refer to FIG. 1B and to FIG. 4A to FIG. 4D, which present a flow chart showing a second embodiment of a high electron mobility transistor forming method and a third embodiment of a high electron mobility transistor of the present disclosure formed by the second embodiment of the forming method. It is noted that, as shown in FIG. 1B and FIG. 4A to FIG. 4D, the differences between the first embodiment of a high electron mobility transistor forming method and the second embodiment of a high electron mobility transistor forming method are S4a and S5a.

S4a: etching the barrier layer to define a source ohmic contact recess and a drain ohmic contact recess, wherein both of the source ohmic contact recess and the drain ohmic contact recess has a sidewall portion and a bottom portion.

In this embodiment, as shown in FIG. 4A and FIG. 4B, the high electron mobility transistor 1b, both the sidewall portions 41b, 51b, and the bottom portions 42b, 52b are located within the barrier layer 30 in the third embodiment. Thus, the same processing method, i.e., S1 to S3 and S6, are omitted. The embodiment having both the sidewall portions 41b, 51b, and the bottom portions 42b, 52b located within the barrier layer 30 is called a shallow recess; i.e., only the barrier layer 30 is etched to define a source ohmic contact recess 40b and a drain ohmic contact recess 50b, and the etching stops within the barrier layer 30 so as to maintain a distance between the bottom portions 42b, 52b and a surface of the channel layer 20. The distance between the bottom portions 42b, 52b and a surface of the channel layer 20 ranges from 0.5 nm to 10 nm.

S5a: depositing an un-doping layer covering the barrier layer, the gate structure, the source ohmic contact recess and the drain ohmic contact recess such that a polarization of two-dimensional electron gas (2DEG) under the bottom portion and is enhanced.

As shown in FIG. 4C and FIG. 4D, for the embodiment of shallow recess structure of the present disclosure, the un-doped layer 60 or high Al fraction are applied to enhance polarization of 2DEG under the bottom portions 42b, 52b, such than electrons will be transported easily to achieve low contact resistance.

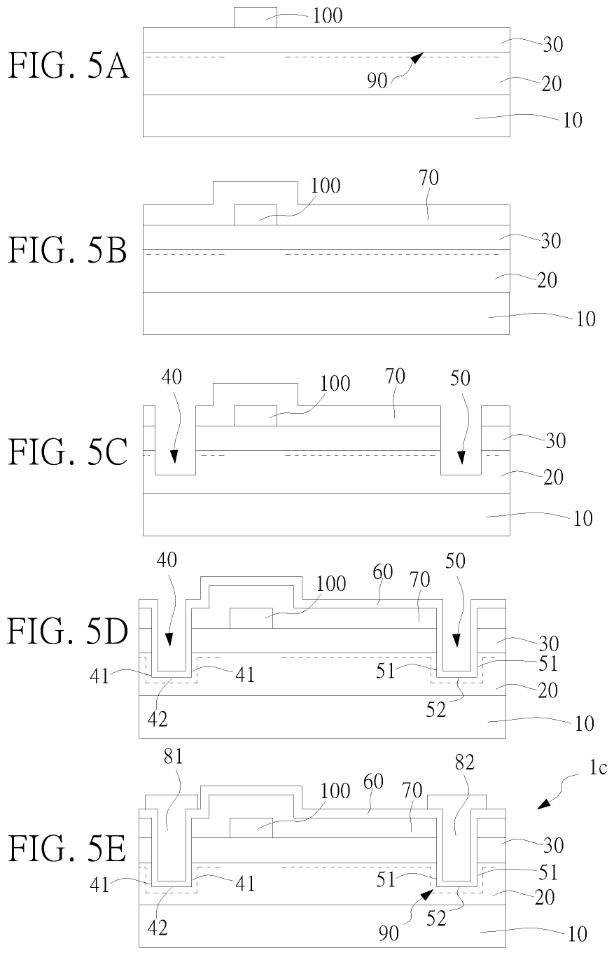

Please refer to FIG. 1C and FIG. 5A to FIG. 5D, which present a flow chart showing a third embodiment of a high electron mobility transistor forming method and a fourth embodiment of a high electron mobility transistor 1c of the present disclosure formed by the third embodiment of the forming method. It is noted that S1 to S3 and S6 in the third embodiment of the forming method are same as those in the first embodiment of the forming method, so the related description is omitted.

As shown in FIG. 1C, before the etching of the barrier layer to define a source ohmic contact recess and a drain ohmic contact recess, the third embodiment of the high electron mobility transistor forming method further includes the following steps:

S41: Depositing a dielectric layer covering the barrier layer and the gate structure.

As shown in FIG. 5B, a dielectric layer 70 is deposited to cover the barrier layer 30 and the gate structure 100. The dielectric layer 70 can be an AlN layer, a SiN layer, a SiOx, or an AlO layer.

S42: Etching the dielectric layer, the barrier layer, and the channel layer to define the source ohmic contact recess and the drain ohmic contact recess.

As shown in FIG. 5C, in this embodiment, the dielectric layer 70, the barrier layer 30, and the channel layer 20 are etched to define the source ohmic contact recess 40 and the drain ohmic contact recess 50. The depth of the source ohmic contact recess 40 and the drain ohmic contact recess 50 ranges from 0.5 nm to a half of a depth of the sum of the depth of the channel layer 20 and the depth of the barrier layer 30(epi layer).

S5b: depositing an un-doping layer covering the barrier layer, the channel layer, the dielectric layer, the source ohmic contact recess and the drain ohmic contact recess and then the electron transporting area is rebuilt at the interface around the bottom portion and the sidewall portion of the source ohmic contact recess and the drain ohmic contact recess.

As shown in FIG. 5D, the un-doped layer 60 covers the channel layer 20, the barrier layer 30, the dielectric layer 70, the source ohmic contact recess 40, and the drain ohmic contact recess 50 such that the electron transporting area 90 is rebuilt at the interface around the sidewall portions 41, 51 and the bottom portions 42, 52 of the source ohmic contact recess 40 and the drain ohmic contact recess 50.

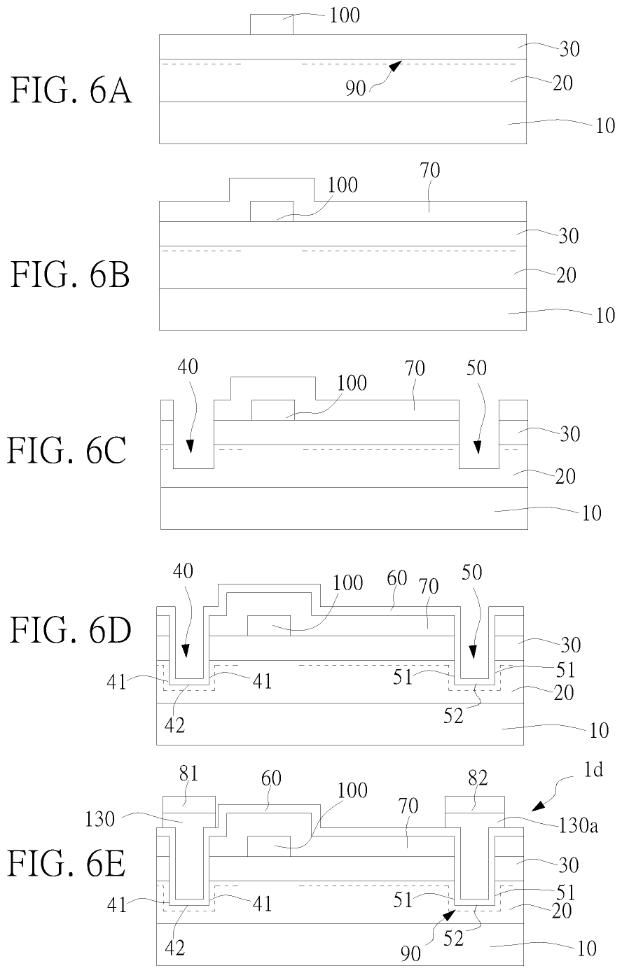

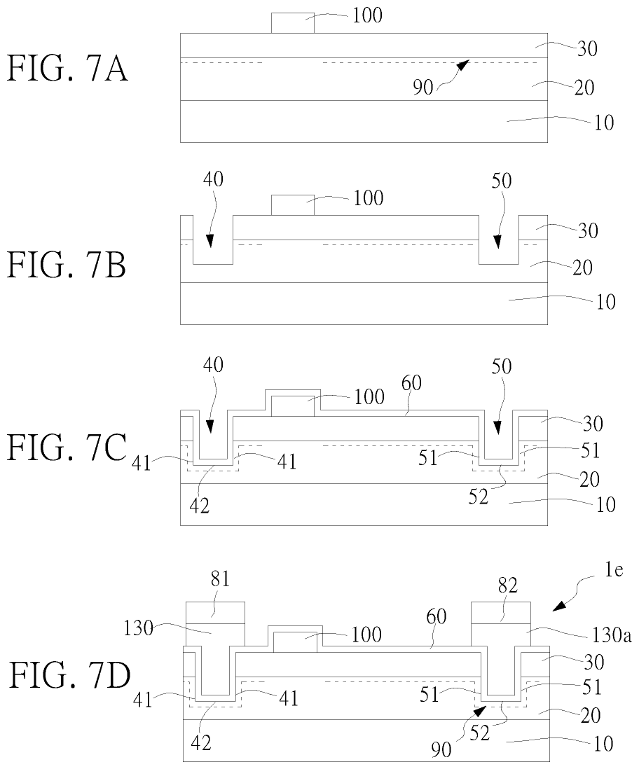

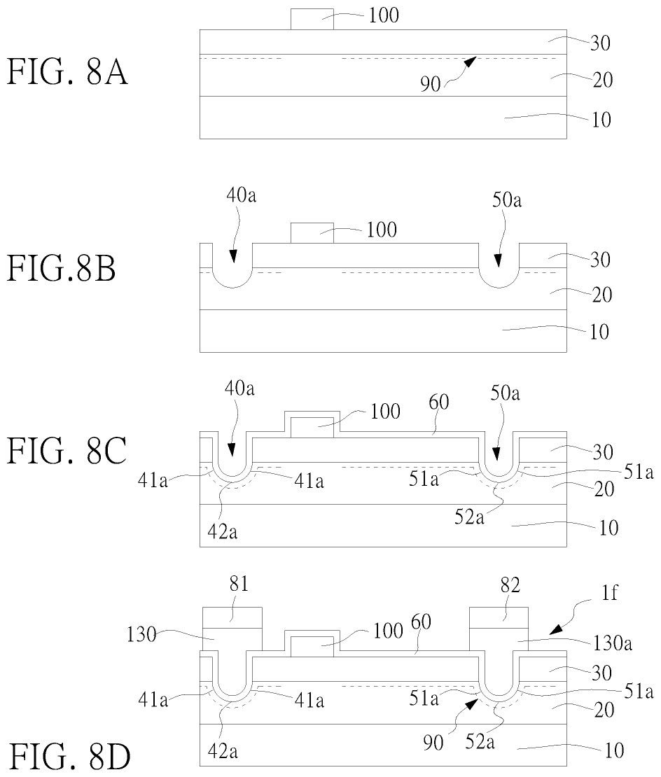

Please refer to FIG. 1D, FIG. 6A to FIG. 6E, FIG. 7A to FIG. 7D, and FIG. 8A to FIG. 8D, which present a flow chart showing a fourth embodiment of a high electron mobility transistor forming method and a fifth embodiment of a high electron mobility transistor 1d, a sixth embodiment of a high electron mobility transistor 1e, and a seventh embodiment of a high electron mobility transistor If of the present disclosure formed by the fourth embodiment of the forming method. It is noted that S1 to S5 in the fourth embodiment of the forming method are same as those in the first embodiment of the forming method, so the related description is omitted.

As shown in FIG. 1D, before the forming of the source ohmic contact 81 and the drain ohmic contact 82, the forming method for the high electron mobility transistor 1d, 1e, and 1f further includes the following steps:

S51: Depositing an n-type nitride base layer or a p-type nitride base layer to cover the un-doped layer on the source ohmic contact recess and the drain ohmic contact recess.

As shown in FIG. 6E, FIG. 7D, and FIG. 8D, n-type nitride base layers 130,130a are deposited to cover the un-doped layer 60 on the source ohmic contact recess 40 and the drain ohmic contact recess 50. The n-type nitride base layers 130, 130a can be an nGaN layer or an nAlGaN layer. It is noted that a p-type nitride base layer also can be deposited to cover the un-doped layer 60 on the source ohmic contact recess 40 and the drain ohmic contact recess 50.

S61: Depositing the source ohmic contact and the drain ohmic contact on the n-type nitride base layer or the p-type nitride base layer.

As shown in FIG. 6E, FIG. 7D, and FIG. 8D, the source ohmic contact 81 and the drain ohmic contact 82 are deposited on the n-type nitride base layers 130, 130a. It is noted that the n-type nitride base layers 130, 130a can be replaced by the p-type nitride base layer, and the embodiments of the high electron mobility transistors 1d, 1e, and 1f are formed respectively.

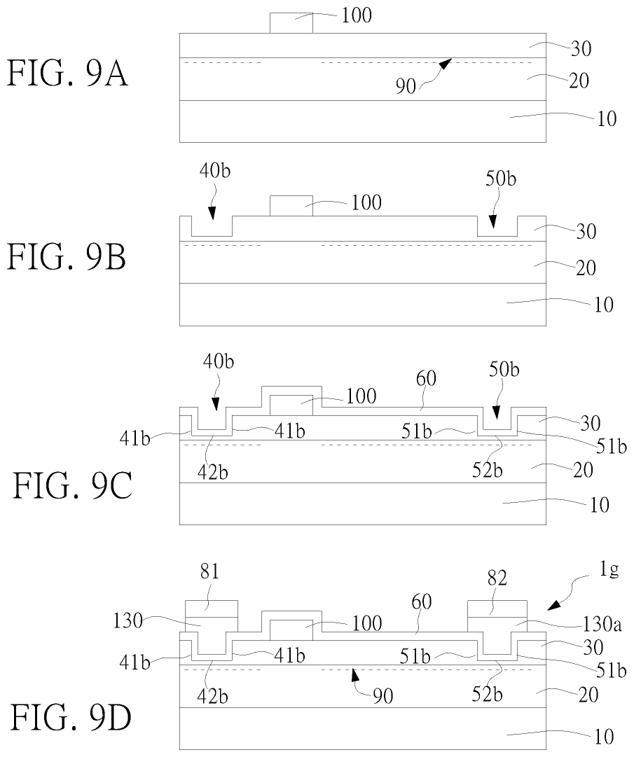

Please refer to FIG. 1E and to FIG. 9A to FIG. 9D, which present a flow chart showing a fifth embodiment of a high electron mobility transistor forming method and an eight embodiment of a high electron mobility transistor of the present disclosure formed by the fifth embodiment of the forming method. It is noted that, as shown in FIG. 1E, the steps S1 to S5a in the fifth embodiment of the forming method are same as those in the second embodiment of the forming method, and steps S51 to S61 in the fifth embodiment are same as those in the fourth embodiment of the forming method, therefore, the related description is omitted.

As shown in FIG. 1E and FIG. 9D, n-type nitride base layers 130,130a are deposited to cover the un-doped layer 60 on the source ohmic contact recess 40 and the drain ohmic contact recess 50. The source ohmic contact 81 and the drain ohmic contact 82 are deposited on the n-type nitride base layers 130, 130a. It is noted that the n-type nitride base layers 130, 130a can be replaced by the p-type nitride base layer, and the eighth embodiment of the high electron mobility transistor 1g is formed consequently.

Please refer back to FIG. 2D, FIG. 3D, and FIG. 4D, which present the first embodiment, the second embodiment, and the third embodiment of the high electron mobility transistors of the present disclosure.

As shown in FIG. 2D, in the first embodiment, the high electron mobility transistors 1 includes a substrate 10, a channel layer 20, a barrier layer 30, a gate structure 100, a source ohmic contact recess 40, a drain ohmic contact recess 50, an un-doped layer 60, a source ohmic contact 81, and a drain ohmic contact 82. The channel layer 20 is disposed on the substrate 10. The barrier layer 30 disposed on the channel layer 20. The gate structure 100 is disposed on the barrier layer 30 such that an electron transporting area 90 is formed at an interface between the barrier layer 30 and the channel layer 20 additional to the interface beneath the gate structure 100. The source ohmic contact recess 40 and the drain ohmic contact recess 50 access the barrier layer 30, wherein each of the source ohmic contact recess 40 and the drain ohmic contact 50 recess has a sidewall portion 41, 51 and a bottom portion 42, 52. The un-doped layer 60 covers the channel layer 20, the barrier layer 30, the gate structure 100, the source ohmic contact recess 40 and the drain ohmic contact recess 50 such that the electron transporting area 90 is rebuilt at the interface around sidewall portions 41, 51 and a bottom portions 42, 52 of the source ohmic contact recess 40 and the drain ohmic contact recess 50. The source ohmic contact 81 and a drain ohmic contact 82 cover the source ohmic contact recess 40 and the drain ohmic contact recess 50 respectively.

It is noted that, in this embodiment, the substrate 10 is a Si, SiC or sapphire substrate, and the channel layer 20 is a graded AlxGa1-xN or AlN/GaN supper lattice layers. The barrier layer 30 is an AlGaN layer and the gate structure 100 is a p-type GaN structure; however, the present disclosure is not limited to this embodiment, a n-type GaN structure or a metal composition layers also applicable. The electron transporting area 90 for enhancing a two-dimensional electron gas (2DEG) is formed at the interface between the barrier layer 30 and the channel layer 20 additional to the interface beneath the gate structure 100. As shown in FIG. 2D, the sidewall portions 41, 51 and the bottom portions 42, 52 of the source ohmic contact recess 40 and the drain ohmic contact recess 50 are formed in a rectangle shape. The depth of the source ohmic contact recess 40 and the drain ohmic contact recess 50 ranges from 0.5 nm to a half of a depth of the sum of the depth of the channel layer 20 and the depth of the barrier layer 30(epi layer).

According to one embodiment of the present disclosure, the un-doped layer 60 can be a GaN layer, an AlN layer, an AlGaN layer, an InAlGaN layer, a high Al fraction layer or an AlN/AlGaN composition layer and formed by atomic layer deposition (ALD) or metal organic chemical vapor deposition (MOCVD). According to one embodiment of the present disclosure, the thickness of the un-doped layer 60 ranges between 0.5 nm and 30 nm. In this embodiment, both the source ohmic contact 81 and the drain ohmic contact 82 are metal stacks made of Ti, Al, TiN, or Si.

As shown in FIG. 3D, the difference between the second embodiment of the high electron mobility transistors 1a and the first embodiment of the high electron mobility transistors 1 is that the sidewall portions 41a, 51a and the bottom portions 42a, 52a are formed in an arc shape in the second embodiment.

As shown in FIG. 4D, the difference between the first embodiment of a high electron mobility transistor 1 and the third embodiment of a high electron mobility transistor 1b is that both the sidewall portions 41b, 51b, and the bottom portions 42b, 52b are located within the barrier layer 30 in the third embodiment. The embodiment having both the sidewall portions 41b, 51b, and the bottom portions 42b, 52b located within the barrier layer 30 is called a shallow recess; i.e., only the barrier layer 30 is etched to define a source ohmic contact recess 40b and a drain ohmic contact recess 50b, and the etching stops within the barrier layer 30 so as to maintain a distance between the bottom portions 42b, 52b and a surface of the channel layer 20. The distance between the bottom portions 42b, 52b and a surface of the channel layer 20 ranges from 0.5 nm to 10 nm. For the embodiment of shallow recess structure of the present disclosure, the un-doped layer 60 or high Al fraction are applied to enhance polarization of 2DEG under the bottom portions 42b, 52b, such than electrons will be transported easily to achieve low contact resistance.

Please refer back to FIG. 5E, which present the fourth embodiment of the high electron mobility transistors of the present disclosure.

As shown in FIG. 5E, the difference between the first embodiment of a high electron mobility transistor 1 and the fourth embodiment of a high electron mobility transistor 1c is that a dielectric layer 70 is deposited to cover the barrier layer 30 and the gate structure 100. The dielectric layer 70 can be an AlN layer, a SiN layer, a SiOx layer or an AlO layer.

Please refer back to FIG. 6E, FIG. 7D, FIG. 8D, and FIG. 9D, which present the fifth embodiment, the six embodiment, the seventh embodiment, and the eighth embodiment of the high electron mobility transistors of the present disclosure.

As shown in FIG. 6E, the difference between the first embodiment of a high electron mobility transistor 1 and the fifth embodiment of a high electron mobility transistor 1d is that dielectric layer 70 and n-type nitride base layers 130,130a are deposited to cover the un-doped layer 60 on the source ohmic contact recess 40 and the drain ohmic contact recess 50. The n-type nitride base layers 130,130a can be an nGaN layer or an nAlGaN layer. It is noted that a p-type nitride base layer also can be deposited to cover the un-doped layer 60 on the source ohmic contact recess 40 and the drain ohmic contact recess 50.

As shown in FIG. 7D, the difference between the first embodiment of a high electron mobility transistor 1 and the sixth embodiment of a high electron mobility transistor 1e is that n-type nitride base layers 130,130a are deposited to cover the un-doped layer 60 on the source ohmic contact recess 40 and the drain ohmic contact recess 50. The n-type nitride base layers 130,130a can be an nGaN layer or an nAlGaN layer. It is noted that a p-type nitride base layer also can be deposited to cover the un-doped layer 60 on the source ohmic contact recess 40 and the drain ohmic contact recess 50.

As shown in FIG. 8D, the difference between the first embodiment of a high electron mobility transistor 1 and the seventh embodiment of a high electron mobility transistor If is that the sidewall portions 41a, 51a and the bottom portions 42a, 52a are formed in an arc shape and n-type nitride base layers 130,130a are deposited to cover the un-doped layer 60 on the source ohmic contact recess 40a and the drain ohmic contact recess 50a. The n-type nitride base layers 130,130a can be an nGaN layer or an nAlGaN layer. It is noted that a p-type nitride base layer also can be deposited to cover the un-doped layer 60 on the source ohmic contact recess 40a and the drain ohmic contact recess 50a.

As shown in FIG. 9D, the difference between the fourth embodiment of a high electron mobility transistor 1b and the eighth embodiment of a high electron mobility transistor 1g is that n-type nitride base layers 130, 130a are deposited between the un-doped layer 60 on the source ohmic contact recess 40b and the drain ohmic contact recess 50b and the source ohmic contact 81 and the drain ohmic contact 82.

The high electron mobility transistor 1 and a high electron mobility transistor forming method have the advantages listed below: the Ron performance of the high electron mobility transistor of the present disclosure is further lowered; the geometric shape of the sidewall portions 41, 51 and the bottom portions 42, 52 increase the electron transporting area 90 such that the source contact resistance and drain contact resistance of the high electron mobility transistor 1 of the present disclosure are improved. The forming method of the present disclosure also solves process control capability issues in the manufacturing of high electron mobility transistors. The increased electron transporting area 90 also enhances the polarization of 2DEG such that electrons can be transported easily. Because of the barrier layer 30 (AlGaN) is etched through to access the channel layer 20, requirements for controlling an ultra-low etching rate, a retained barrier thickness, and a thermal budget can be suspended.

It should be noted that many of the above-mentioned embodiments are given as examples for description, and the scope of the present invention should be limited to the scope of the following claims and not limited by the above embodiments.

What is claimed is:

1. A high electron mobility transistor (HEMT) forming method comprising:
forming a channel layer on a substrate;
forming a barrier layer on the channel layer;
defining a gate structure on the barrier layer such that an electron transporting area is formed at an interface between the barrier layer and the channel layer additional to the interface beneath the gate structure;
etching the barrier layer to define a source ohmic contact recess and a drain ohmic contact recess, wherein each of the source ohmic contact recess and the drain ohmic contact recess has a bottom portion and a sidewall portion;
depositing an un-doped layer covering the barrier layer, the gate structure, the source ohmic contact recess and the drain ohmic contact recess such that a polarization of two-dimensional electron gas (2DEG) under the bottom portion is enhanced; and
depositing a source ohmic contact and a drain ohmic contact covering the source ohmic contact recess and the drain ohmic contact recess.

2. The method as claimed in claim 1, wherein the sidewall portion and the bottom portion are formed in an arc shape, a rectangle shape, a trapezoidal shape or a U shape.

3. The method as claimed in claim 1, wherein the un-doped layer can be a GaN layer, an AlN layer, an AlGaN layer, an InAlGaN layer, a high Al fraction layer or an AlN/AlGaN composition layer.

4. The method as claimed in claim 1, wherein both the sidewall portion and the bottom portion are located within the barrier layer and a distance between the bottom portion and a surface of the channel layer ranges from 0.5 nm to 10 nm.

5. The method as claimed in claim 1, wherein the source ohmic contact recess and the drain ohmic contact recess are defined by etching through the barrier layer and accessing the channel layer and the un-doped layer further covers the channel layer, such that an electron transporting area is rebuilt at the interface around the bottom portion and the sidewall portion of the source ohmic contact recess and the drain ohmic contact recess.

6. The method as claimed in claim 5, wherein a depth of the source ohmic contact recess and the drain ohmic contact recess ranges from 0.5 nm to a half of a depth of the sum of the depth of the channel layer and the depth of the barrier layer.

7. The method as claimed in claim 5, wherein before the etching of the barrier layer to define the source ohmic contact recess and the drain ohmic contact recess, the method further comprises:
depositing a dielectric layer covering the barrier layer and the gate structure; and
etching the dielectric layer, the barrier layer, and the channel layer to define the source ohmic contact recess and the drain ohmic contact recess.

8. The method as claimed in claim 7, wherein the depth of the source ohmic contact recess and the drain ohmic contact recess ranges from 0.5 nm to a half of a depth of the sum of the depth of the channel layer and the depth of the barrier layer.

9. The method as claimed in claim 5, wherein before the forming of the source ohmic contact and the drain ohmic contact, the method further comprises:
depositing an n-type nitride base layer or a p-type nitride base layer to cover the un-doped layer on the source ohmic contact recess and the drain ohmic contact recess; and
depositing the source ohmic contact and the drain ohmic contact on the n-type nitride base layer or the p-type nitride base layer.

10. The method as claimed in claim 1, wherein the thickness of the un-doped layer ranges from 0.5 nm to 30 nm.

11. A high electron mobility transistor (HEMT) comprising:
a substrate;
a channel layer disposed on the substrate;
a barrier layer disposed on the channel layer;
a gate structure disposed on the barrier layer such that an electron transporting area is formed at an interface between the barrier layer and the channel layer additional to the interface beneath the gate structure;
a source ohmic contact recess and a drain ohmic contact recess accessing the barrier layer, wherein each of the source ohmic contact recess and the drain ohmic contact recess has a bottom portion and a sidewall portion;
an un-doped layer, covering the barrier layer, the gate structure, the source ohmic contact recess and the drain ohmic contact recess such that a polarization of two-dimensional electron gas (2DEG) under the bottom portion is enhanced; and
a source ohmic contact and a drain ohmic contact covering the source ohmic contact recess and the drain ohmic contact recess.

12. The high electron mobility transistor as claimed in claim 11, wherein the sidewall portion and the bottom portion are formed in an arc shape, a rectangle shape, a trapezoidal shape, or a U shape.

13. The high electron mobility transistor as claimed in claim 11, wherein the un-doped layer can be a GaN layer, an AlN layer, an AlGaN layer, an InAlGaN layer, a high Al fraction layer or an AlN/AlGaN composition layer, and the thickness of the un-doped layer ranges from 0.5 nm to 30 nm.

14. The high electron mobility transistor as claimed in claim 11, wherein both the sidewall portion and the bottom portion are located within the barrier layer, and a distance between the bottom portion and a surface of the channel layer ranges from 0.5 nm to 10 nm.

15. The high electron mobility transistor as claimed in claim 11, wherein the un-doped layer further covers the channel layer and the source ohmic contact recess and the drain ohmic contact recess are defined by etching through the barrier layer and accessing the channel layer such that an electron transporting area is rebuilt at the interface around the bottom portion and the sidewall portion of the source ohmic contact recess and the drain ohmic contact recess.

16. The high electron mobility transistor as claimed in claim 15, wherein a depth of the source ohmic contact recess and the drain ohmic contact recess ranges from 0.5 nm to half of the depth of the sum of the depth of the channel layer and the depth of the barrier layer.

17. The high electron mobility transistor as claimed in claim 15, further comprising a dielectric layer disposed between the un-doped layer and the barrier layer.

18. The high electron mobility transistor as claimed in claim 17, wherein the depth of the source ohmic contact recess and the drain ohmic contact recess ranges from 0.5 nm to a half of the depth of the sum of the depth of the channel layer and the depth of the barrier layer

19. The high electron mobility transistor as claimed in claim 15, further comprising an n-type nitride base layer or a p-type nitride base layer covering both the source ohmic contact recess and the drain ohmic contact recess.

20. The high electron mobility transistor as claimed in claim 19, wherein the source ohmic contact and the drain ohmic contact are deposited on the n-type nitride base layer or the p-type nitride base layer.
